(19) United States
(12) Patent Application Publication
(10) Pub. No.: US 2012/0241722 A1
(43) Pub. Date: Sep. 27, 2012

(54) FIELD EFFECT TRANSISTOR

(76) Inventors: Keiji Ikeda, Yokohama-Shi (JP); Toshifumi Irisawa, Tokyo (JP); Toshinori Numata, Kamakura-Shi (JP); Tsutomu Tezuka, Tsukuba-shi (JP)

(21) Appl. No.: 13/240,246

(22) Filed: Sep. 22, 2011

(30) Foreign Application Priority Data
Mar. 25, 2011 (JP) 2011-067655

(51) Int. Cl. H01L 29/165

(52) U.S. Cl. 257/19; 257/E29.085

(57) ABSTRACT

A field effect transistor according to an embodiment includes: a semiconductor layer; a source region and a drain region formed at a distance from each other in the semiconductor layer; a gate insulating film formed on a portion of the semiconductor layer, the portion being located between the source region and the drain region; a gate electrode formed on the gate insulating film; and a gate sidewall formed on at least one of side faces of the gate electrode, the side faces being located on a side of the source region and on a side of the drain region, the gate sidewall being made of a high dielectric material. The source region and the drain region are separately-placed from the corresponding side faces of the gate electrode.

### CROSS-REFERENCE TO RELATED APPLICATION

This application is based upon and claims the benefit of priority from prior Japanese Patent Application No. 2011-67655 filed on Mar. 25, 2011 in Japan, the entire contents of which are incorporated herein by reference.

### FIELD

Embodiments described herein relate generally to a field effect transistor.

### BACKGROUND

Conventionally, a field effect transistor (FET) having steep Subthreshold slope characteristics, such as a tunneling field effect transistor (hereinafter also referred to as TFET), has an asymmetrical source/drain structure in which the source/drain regions have different conductivity types from each other (p⁺-i-n⁺). In such an asymmetrical source/drain structure, the source region, the channel region, and the drain region are formed of p-i-n junctions formed through ion implantation. The BTBT (Band To Band Tunneling) in the source junction determines the current drive capability. Therefore, to improve the drive current, the tunnel barrier needs to be thinned to 1 nm to 3 nm by forming a high-doping concentration junction with a steep profile in the source junction.

Meanwhile, an off-leak current is determined by the BTBT in the drain junction. Therefore, in a device designed to consume less power, the tunnel barrier needs to be made thicker and the leakage current needs to be made lower, by forming a low-doping concentration junction with a gentle profile as the junction between the channel region and the drain region.

There is a case where the FETs forming an inverter circuit and a two-input NAND circuit that are the fundamental circuits in a CMOS logic are FETs, each having a symmetrical structure in which the source region and the drain region have the same conductivity type. The problems described below do not occur in such a case, but do occur in a case where the FETs forming the inverter circuit and the two-input NAND circuit are FETs, each having an asymmetrical structure in which the source region and the drain region have different conductivity types from each other.

In the case where the source/drain structure is symmetrical, p-FET and n-FET regions vertically stacked are separated at a long distance from each other by an ion implantation mask, so that the p-FET and the n-FET can be readily formed separately from each other.

In the case where the source/drain structure is asymmetrical, on the other hand, the n-type region and the p-type region need to be formed separately from each other, with the gate region being the boundary. If the gate length is 50 nm or less in such a structure, forming the n-type region and the p-type region separately from each other is considered unrealistic, in view of an alignment accuracy of lithography. Also, to form a high-doping concentration junction with a steep profile in the source junction, and to form a low-doping concentration junction with a gentle profile in the drain junction, ion implantation directions need to be aligned. Therefore, the orientations of the source region and the drain region of the FET forming the circuit need to be aligned. Further, in a case where a two-input NAND circuit is formed, n-FETs are vertically stacked, and there are regions that serve as the source region and the drain region of two n-FETs. Such a circuit layout cannot be formed in the case where the source/drain regions form an asymmetrical structure. In the case where the source/drain regions form a symmetrical structure, no problems occur even if there are regions that serve as the source regions and the drain regions of the two n-FETs.

As described above, in the case where the source/drain regions form an asymmetrical structure, a conventional circuit design technique cannot be applied as it is to the device layout, and there are the problems of an area increase and a cost increase that accompany a change of layout design.

### BRIEF DESCRIPTION OF THE DRAWINGS

FIGS. 1(a) and 1(b) are cross-sectional views of a transistor according to a first embodiment;

FIGS. 2(a) and 2(b) are diagrams for explaining an operation of the transistor according to the first embodiment;

FIGS. 3(a) and 3(b) are diagrams for explaining an operation of the transistor according to the first embodiment;

FIG. 4 is a cross-sectional view of a transistor according to a modification of the first embodiment;

FIGS. 5(a) and 5(b) are diagrams for explaining a transistor according to a second embodiment;

FIG. 6 is a cross-sectional view of a transistor of a comparative example;

FIG. 7 is a graph showing I-V characteristics of the comparative example;

FIG. 8 is a graph for explaining an off-leak current in the transistor according to the first or second embodiment;

FIG. 9 is a cross-sectional view of a transistor according to a third embodiment;

FIG. 10 is a graph for explaining the I-V characteristics of the transistor according to the third embodiment;

FIG. 11 is a cross-sectional view of a transistor according to a fourth embodiment;

FIG. 12 is a cross-sectional view for explaining an example method of manufacturing the transistor according to the fourth embodiment;

FIG. 13 is a cross-sectional view for explaining another example method of manufacturing the transistor according to the fourth embodiment;

FIG. 14 is a cross-sectional view of a transistor according to a fifth embodiment;

FIG. 15 is a cross-sectional view of a transistor according to a sixth embodiment;

FIGS. 16(a), 16(b) are cross-sectional views for explaining an example method of manufacturing the transistor according to the sixth embodiment;

FIG. 17 is a cross-sectional view showing a method of manufacturing a COMS transistor according to a seventh embodiment;

FIG. 18 is a cross-sectional view showing a method of manufacturing a COMS transistor according to the seventh embodiment;

FIG. 19 is a cross-sectional view showing a method of manufacturing a COMS transistor according to the seventh embodiment;

FIG. 20 is a cross-sectional view showing a method of manufacturing a COMS transistor according to the seventh embodiment;

FIG. 21 is a cross-sectional view showing a method of manufacturing a COMS transistor according to the seventh embodiment;

FIG. 22 is a cross-sectional view showing a method of manufacturing a COMS transistor according to the seventh embodiment;

FIG. 23 is a cross-sectional view showing a method of manufacturing a COMS transistor according to the seventh embodiment; and

FIG. 24 is a cross-sectional view showing a method of manufacturing a COMS transistor according to the seventh embodiment;

### DETAILED DESCRIPTION

A field effect transistor according to an embodiment includes: a semiconductor layer; a source region and a drain region formed at a distance from each other in the semiconductor layer; a gate insulating film formed on a portion of the semiconductor layer, the portion being located between the source region and the drain region; a gate electrode formed on the gate insulating film; and a gate sidewall formed on at least one of side faces of the gate electrode, the side faces being located on a side of the source region and on a side of the drain region, the gate sidewall being made of a high dielectric material. The source region and the drain region are separately-placed from the corresponding side faces of the gate electrode.

The following is a description of embodiments, with reference to the accompanying drawings.

### First Embodiment

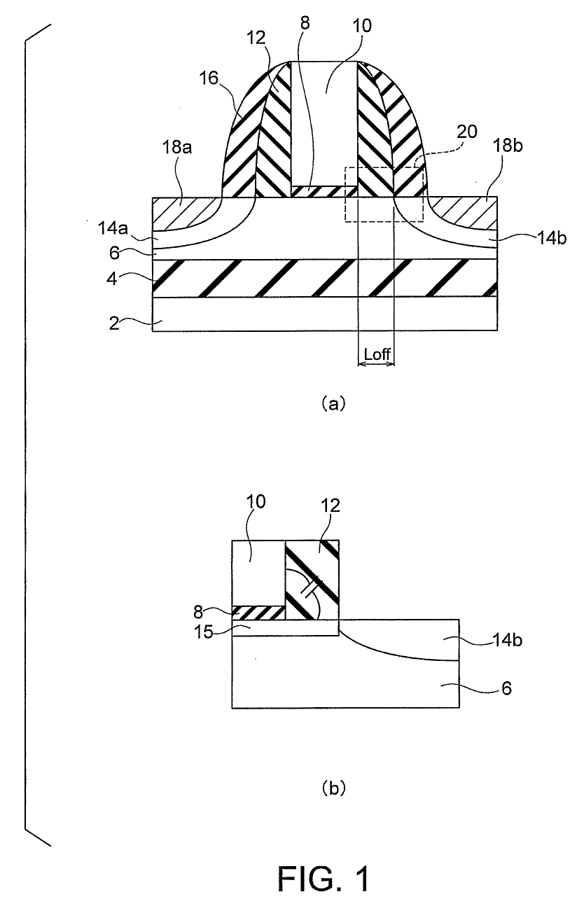

A field effect transistor (hereinafter also referred to as a transistor) according to a first embodiment is shown in FIGS. 1(a) and 1(b). FIG. 1(a) is a cross-sectional view of the transistor of the first embodiment. FIG. 1(b) is an enlarged view of a region 20 surrounded by the dashed line shown in FIG. 1(a). The transistor of the first embodiment is formed on a semiconductor substrate that includes a semiconductor layer 2, an insulating film 4 formed on the semiconductor layer 2, and a semiconductor layer 6 formed on the insulating film 4. A Si layer is used as the semiconductor layer 2, for example. A Si₁₋ₓGeₓ (0≦x≦1) layer is used as the semiconductor layer 6. In a case where the semiconductor layer 6 is not a Si layer or where the semiconductor layer 6 contains Ge, the semiconductor layer 6 preferably has strains. In the following description, the semiconductor layer 6 is a Ge layer. A gate insulating film 8 is formed on the Ge layer 6, and a gate electrode 10 is formed on the gate insulating film 8. A film made of SiO₂, SiON, GeO₂, GeON, HfO₂, Al₂O₃, HfAlₓO_{y}, HfₓLa_{y}O, LaₓO_{y}, LaₓZr_{y}O, ZrₓO_{y} or the like, or a stacked film of some of those materials is used as the gate insulating film 8.

First gate sidewalls (hereinafter also referred to as first sidewalls) 12 made of a high dielectric material or a dielectric material having a dielectric constant of 18 or higher, for example, is formed on the side faces of the gate electrode 10. Examples of high dielectric materials that can be used as the first sidewalls 12 include oxides, oxynitrides, silicates, or aluminates each containing at least one element selected from the group consisting of Hf, Zr, Al, Y, La, Ta, Pr, Ce, Sr, Ti, and Dy. Specifically, the examples include HfO₂, ZrO₂, Y₂O₃, La₂O₃, TiO₂, TaOₓN_{y}, SrₓTi_{y}O, LaZrO₃, LaAlO₃, HfON, HfSiOₓ, HfSiON, HfSiGeOₓ, HfSiGeON, HfGeOₓ, HfSiGeON, ZrON, ZrSiOₓ, ZrSiON, ZrSiGeOₓ, ZrSiGeON, ZrGeOₓ, ZrSiGeON, HfAlₓO_{y}, HfLaO, LaₓZr_{y}O, or LaₓO_{y}.

Further, second gate sidewalls (hereinafter also referred to as the second sidewalls) 16 made of an insulator are formed on the surfaces of the first sidewalls 12 on the opposite sides from the gate electrode 10. The material of the second sidewalls 16 may not be a high dielectric material, and may be SiO₂, SiN, GeN, or the like. The second sidewalls 16 are used to form the later described source electrode 18a and drain electrode 18b in a self-alignment manner, and do not need to be formed if the source electrode 18a and the drain electrode 18b are formed at distances from the end portions of the first sidewalls 12.

A source region 14a and a drain region 14b are formed in portions of the semiconductor layer 6 on the opposite sides of the first sidewalls 12 from the gate electrode 10. That is, the source region 14a and the drain region 14b are in an offset state with respect to the gate electrode 10 (FIG. 1(a)). The offset L_{off} is preferably larger than 0 nm but smaller than 10 nm. When the dielectric constant of the first sidewalls 12 is approximately 20, the offset L_{off} is preferably larger than 0 nm but smaller than 5 nm, so as to sufficiently invert the region to be an extension region by a fringe electric field from the gate electrode end, and to reduce parasitic resistance. The source electrode 18a is formed in the source region 14a on the opposite side of the corresponding second sidewall 16 from the gate electrode 10, and the drain electrode 18b is formed in the drain region 14b on the opposite side of the corresponding second sidewall 16 from the gate electrode 10. That is, in the semiconductor layer 6, the source region 14a and the drain region 14b are formed at distances from the gate electrode 10, and the source electrode 18a and the drain electrode 18b are formed at even longer distances from the gate electrode 10. Accordingly, the source region 18a is located further away from the gate electrode 10 than the source region 14a is, and the drain electrode 18b is located further away from the gate electrode 10 than the drain region 14b is.

The source region 14a and the drain region 14b are positioned so as to be symmetric with respect to the gate electrode 10, and the source electrode 18a and the drain electrode 18b are also positioned so as to be symmetric with respect to the gate electrode 10. In a case where the transistor of this embodiment is an n-channel transistor, the source region 14a and the drain region 14b have an n-type dopant such as P, As, or Sb introduced into the semiconductor layer 6. In a case where the transistor of this embodiment is a p-channel transistor, the source region 14a and the drain region 14b have a p-type dopant such as B, Ga, or In introduced into the semiconductor layer 6. The concentration of the dopant is 1×10¹⁵ cm⁻². The concentration of the dopant is preferably in the range of 5×10¹⁴ to 2×10¹⁵ cm⁻². The source electrode 18a and the drain electrode 18b are made of an intermetallic compound of the semiconductor layer 6 and a transition metal such as Er, Y, Yb, or Dy, Ni, Pt, a Ni alloy, a Pt alloy, or the like. For example, in a case where the semiconductor layer 6 is made of Ge, the source electrode 18a and the drain electrode 18b are made of an intermetallic compound containing NiGe or PtGe.

In the first embodiment, extension regions are not formed in the semiconductor layer 6, but a high dielectric material is used as the first gate sidewalls 12. Accordingly, the first sidewalls 12 made of the high dielectric material efficiently transmit the fringe electric field of the gate electrode 10, the fringe electric field being generated when the transistor is turned on, to the channel region in the semiconductor layer 6, and induces an inversion layer 15 in the channel region, as shown in FIG. 1(b). While the transistor is on, the inversion layer 15 serves as an extension region. It should be noted that the channel region is the region in the semiconductor layer 6 located between the source region 14a and the drain region 14b.

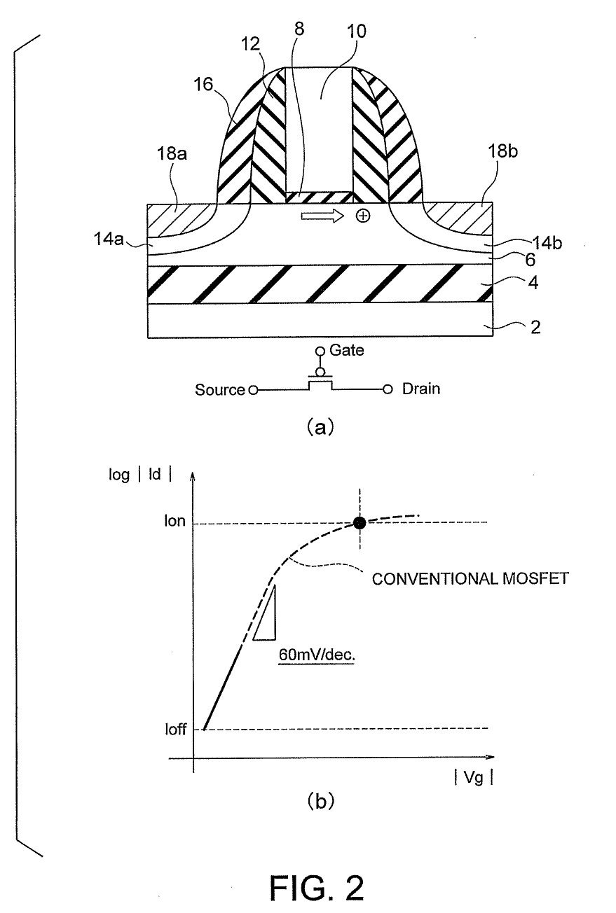

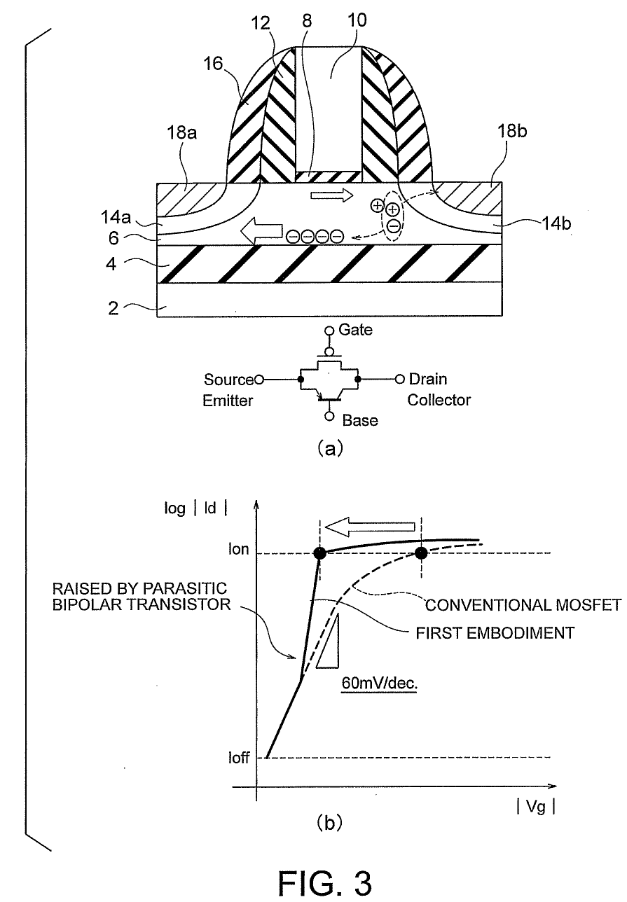

Referring now to FIGS. 2(a), 2(b), 3(a), and 3(b), the operating principles of the transistor according to the first embodiment are described below. FIG. 2(a) is a cross-sectional view showing the channel region observed immediately after a voltage starts being applied to the gate electrode 10 of the transistor of the first embodiment. FIG. 2(b) is a graph showing the relationship between the drain current Id and the gate voltage Vg in that situation. FIG. 3(a) is a cross-sectional view showing the channel region observed when the voltage being applied to the gate electrode 10 is increased from the voltage applied in the situation illustrated in FIGS. 2(a) and 2(b). FIG. 3(b) is a graph showing the relationship between the drain current Id and the gate voltage Vg in that situation. In FIGS. 2(b) and 3(b), Ion represents the current with which the transistor is put into an ON state, and Ioff represents the current with which the transistor is put into a completely OFF state.

As shown in FIGS. 2(a) and 2(b), in the initial stage immediately after the transistor starts increasing its gate voltage from the OFF state, the transistor performs an operation of a conventional MOSFET. That is, as shown in FIG. 2(b), as the absolute value of the gate voltage Vg becomes larger, the absolute value of the drain current Id becomes larger, having a slope of 60 mV/dec. It should be noted that a conventional MOSFET is a transistor in which a high dielectric material is not used as the gate sidewalls 12, and extension regions are formed in the source region and the drain region, respectively.

When the absolute value of the voltage being applied to the gate electrode 10 is further increased from the voltage applied in the situation illustrated in FIGS. 2(a) and 2(b), carriers (holes in the case of a p-channel transistor, for example) injected from the source region 14a are accelerated by a drain electricfield, and collide with the edge portion of the drain region 14b, causing an impact ionization phenomenon. Some of the minority carriers (electrons, for example) generated by the impact ionization phenomenon are accumulated in the vicinity of the interface between the semiconductor layer 6 and the insulating film 4. Because of the accumulated minority carriers, a parasitic bipolar transistor formed of the drain region 14b, the channel region, and the source region 14a is turned on. The current in the subthreshold region is amplified by the current amplifying effect of the parasitic bipolar transistor. Through the current amplification in the subthreshold region, an S-value exceeding 60 mV/dec can be realized (see FIG. 3(b)). That is, the absolute value of the gate voltage Vg required for the transistor to reach the ON-state current Ion can be made smaller than that required in a conventional MOSFET. At this point, it is more preferable to facilitate the accumulation by applying a backgate voltage to the semiconductor layer 2.

As described above, according to the first embodiment, steep S-value characteristics can be achieved. Also, since the transistor has a symmetrical structure in which the source/drain regions have the same conductivity type, a conventional circuit design technique can be used as it is in the device layout. Accordingly, the area increase and the cost increase that accompany a change of design can be restrained.

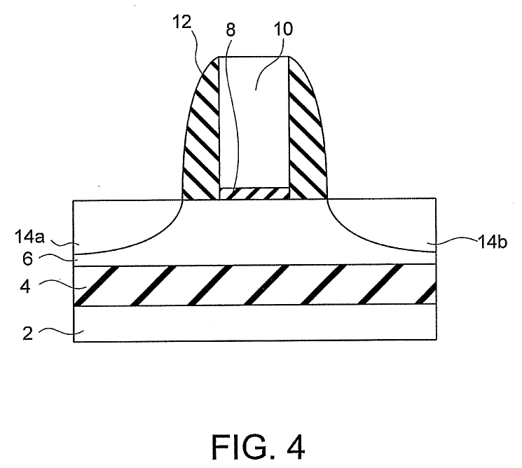

In the first embodiment, the source electrode 18a and the drain electrode 18b made of an intermetallic compound are formed in the source region 14a and the drain region 14b, respectively. However, as in a modification illustrated in FIG. 4, the source electrode 18a and the drain electrode 18b made of an intermetallic compound do not need to be formed in the source region 14a and the drain region 14b, respectively. In such a case, the second sidewalls 16 become unnecessary. This modification can achieve the same effects as those of the first embodiment.

### Second Embodiment

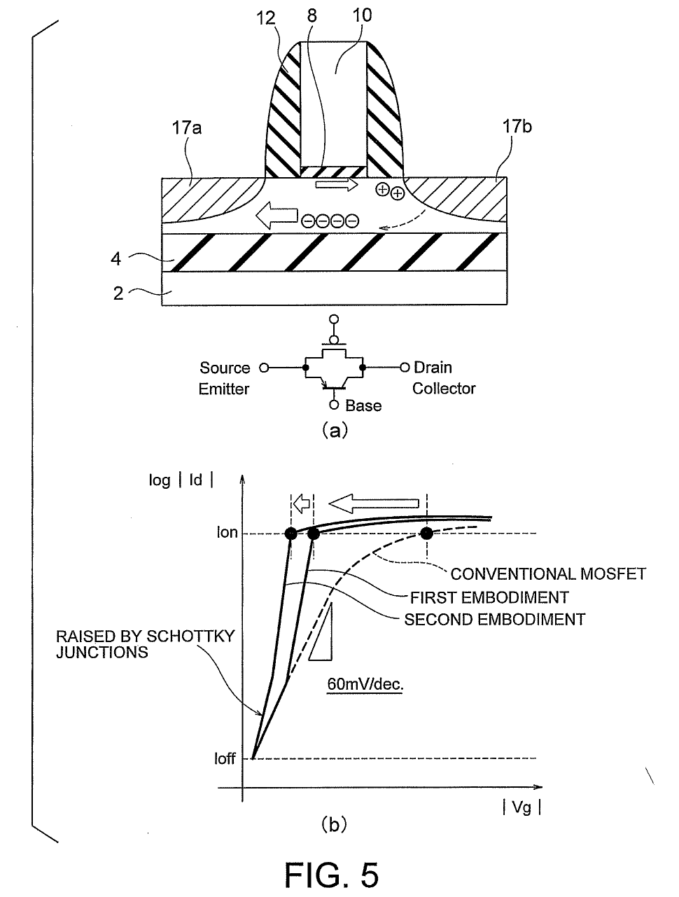

Referring now to FIGS. 5(a) and 5(b), a transistor according to a second embodiment is described below. FIG. 5(a) is a cross-sectional view of the transistor according to the second embodiment. FIG. 5(b) is a graph showing the I-V characteristics of the transistor according to the second embodiment.

The transistor of the second embodiment is the same as the transistor of the first embodiment illustrated in FIG. 1(a), except that each of the source region and the drain region is made of an intermetallic compound. That is, the source region and the drain region are a source region 17a and a drain region 17b that are made of metal (an intermetallic compound), and are designed to have schottky junctions with the semiconductor layer 6. By forming such a metallic source/drain structure, carriers are injected into the channel region from the metallic source region 17a. With this structure, an S-value exceeding the limiting value of 60 mV/dec, which is set due to thermal diffusion of carriers, can be realized by the tunneling carrier injection, as shown in FIG. 5(b), and the S-value in the initial rising stage can be further improved compared with that in the first embodiment.

In a case where the transistor is an n-channel transistor in the second embodiment, a dopant for schottky barrier modulation, such as at least one element of S and Se, is preferably segregated in the interfaces between the semiconductor layer 6 and the source and drain regions 17a and 17b.

In the second embodiment, steep S-value characteristics can be achieved, as in the first embodiment. Also, since the transistor has a symmetrical structure in which the source/drain regions have the same conductivity type, a conventional circuit design technique can be used as it is in the device layout. Accordingly, the area increase and the cost increase that accompany a change of design can be restrained.

### COMPARATIVE EXAMPLE

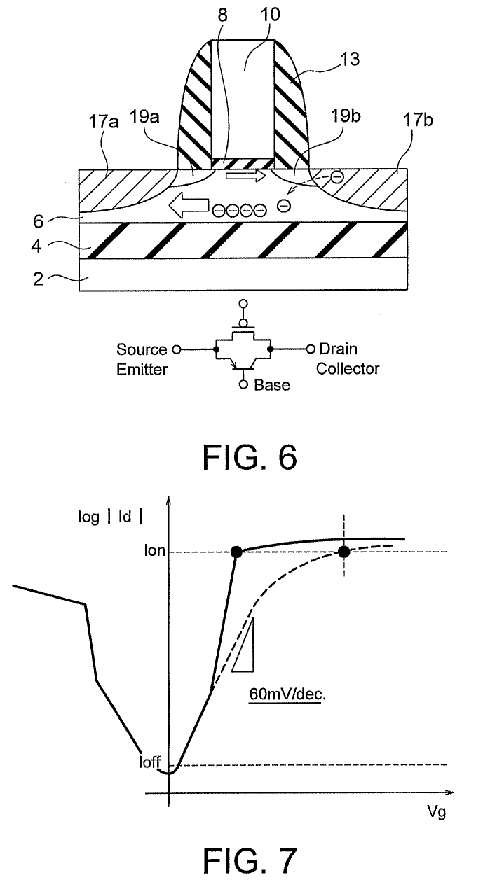

As a comparative example of the first and second embodiments, the transistor shown in FIG. 6 is manufactured. The transistor of this comparative example is the same as the transistor of the second embodiment illustrated in FIG. 5(a), except that the sidewalls 12 made of a high dielectric material are replaced with sidewalls 13 made of an insulator with a low dielectric constant, such as SiN, extension regions 19a and 19b formed between the channel region and the source and drain regions 17a and 17b by introducing a dopant into the semiconductor layer 6, and the extension regions 19a and 19b extend into the channel region located immediately below the gate electrode 10. That is, when viewed from above, the gate electrode 10 partially overlaps with the extension regions 19a and 19b. The extension region 19a and the source region 17a made of a metal form a source region in the broad sense, and the extension region 19b and the drain region 17b made of a metal form a drain region in the broad sense.

In the transistor of this comparative example, GIDL (Gate Induced Drain Leakage) occurs in the drain region overlapping with the gate electrode, when the transistor is in an OFF state, as shown in FIG. 6. Therefore, if the voltage Vg being applied to the gate electrode is made lower than the voltage at which the transistor is turned off, the off-leak current is amplified by the above-described parasitic bipolar effect. Particularly, in a case where Ge with a narrow bandgap is used as the semiconductor layer 6, the amplification of the off-leak current is more conspicuous, since the GIDL is large.

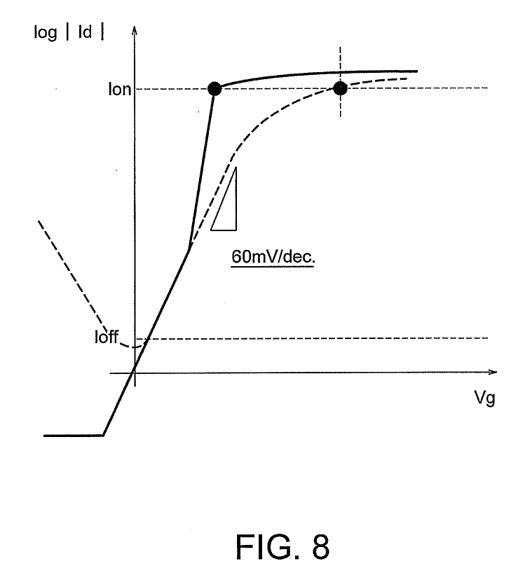

In the first and second embodiments, on the other hand, the source region and the drain region are in an offset state with respect to the gate electrode, and the extension regions formed by introducing a dopant are not provided. Therefore, even if the voltage Vg being applied to the gate electrode 10 is made even lower than the voltage at which the transistor is turned off, as shown in FIG. 8, only an accumulation layer is formed in the channel region due to the fringe electric field of the gate electrode 10, and an inversion layer is not formed when the transistor is turned off. Accordingly, the generation of the GIDL current can be restrained, as shown in FIG. 8. As the generation of the GIDL current can be restrained, the GIDL current is not amplified by the parasitic bipolar transistor, and the rapid off-leak current increase shown in FIG. 7 does not occur (FIG. 8).

### Third Embodiment

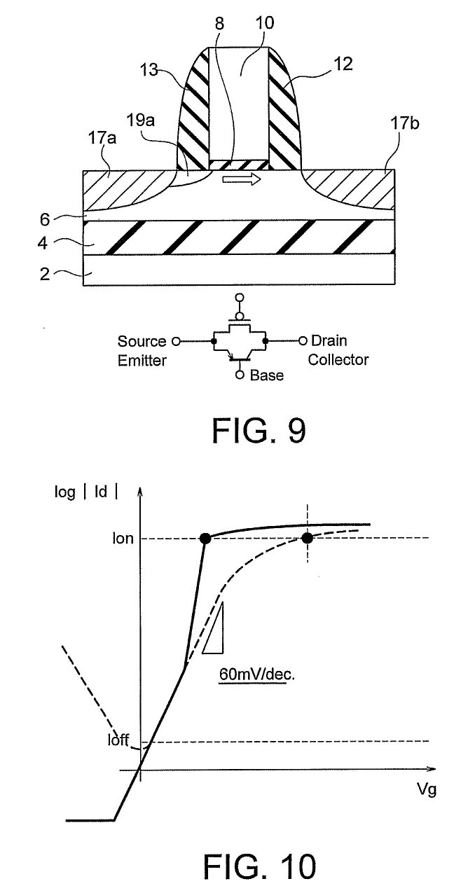

FIG. 9 shows a transistor according to a third embodiment. The transistor of the third embodiment is the same as the transistor of the second embodiment, except that an extension region 19a formed by introducing a dopant is provided on a side of the source region 17a, a sidewall 12 made of a high dielectric material is provided as the sidewall on the drain side, and a sidewall 13 made of a low dielectric material (SiO₂ or SiN, for example) is provided as the sidewall on the source side. This structure can also be applied to the first embodiment illustrated in FIG. 1. That is, in a transistor having the source region 14a and the drain region 14b that are formed between the semiconductor layer 6 and the source and drain electrodes 18a and 18b by introducing a dopant, an extension region formed by introducing a dopant can be provided on a side of the source region 14a, the sidewall on the drain side can be a sidewall made of a high dielectric material, and the sidewall on the source side can be a sidewall made of a low dielectric material, as in this embodiment. Furthermore, an extension region formed by introducing a dopant can be provided on a side of the source region 14a, the sidewalls on the drain and source sides can be sidewalls made of a high dielectric material.

FIG. 10 shows the I-V characteristics of a transistor having the above-described structure. As can be seen from FIG. 10, a high field region by drain overlap is not formed when the transistor is turned off, and the generation of the GIDL current is restrained. As the generation of the GIDL current is restrained, the off-leak current is not amplified by the parasitic bipolar transistor, and a rapid off-leak current increase does not occur.

Also, since an extension region is provided on the source region side, the parasitic resistance at the source end can be reduced when the transistor is in an ON state.

In the third embodiment, the transistor also has a symmetrical structure in which the source/drain regions have the same conductivity type, as in the first or second embodiment. Therefore, a conventional circuit design technique can be used as it is in the device layout. Accordingly, the area increase and the cost increase that accompany a change of design can be restrained.

### Fourth Embodiment

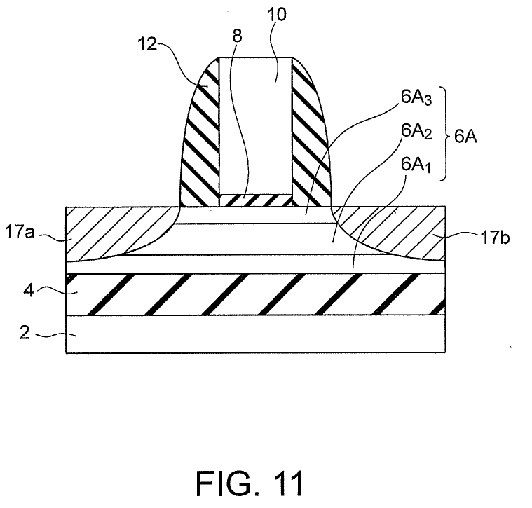

FIG. 11 shows a transistor according to a fourth embodiment. The transistor of the fourth embodiment is the same as the transistor of the second embodiment illustrated in FIG. 5, except that the semiconductor layer 6 is replaced with a semiconductor layer 6A made of SiGe, and the semiconductor layer 6A has a three-layer structure that includes a Si layer 6A₁ formed on the side of the oxide film 4, a Si layer 6A₃ formed on the side of the gate insulating film 8, and a Si₁₋ₓGeₓ (0<x≦1) layer interposed in between. In the following description, the Si₁₋ₓGeₓ (0<x≦1) layer is a Ge layer 6A₂. In that case, a layer in which Si and Ge coexist is formed in the vicinity of the interface between the Si layer 6A₁ and the Ge layer 6A₂, and in the vicinity of the interface between the Si layer 6A₃ and the Ge layer 6A₂.

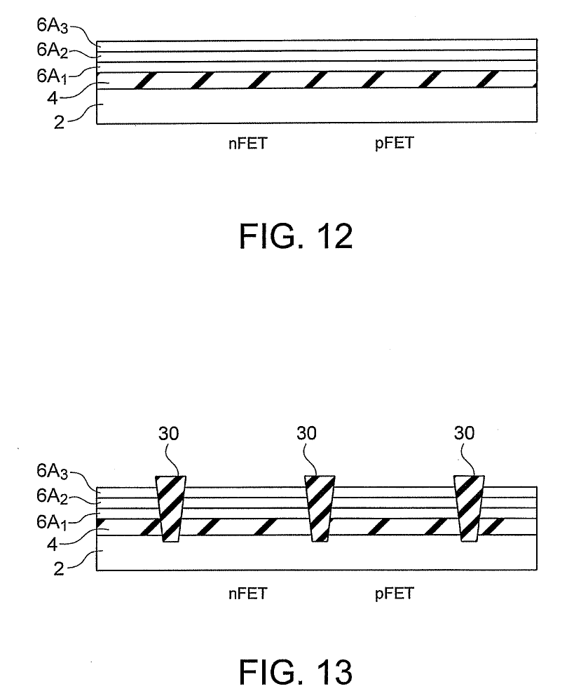

There are the following two methods for manufacturing the semiconductor layer 6A having the above described three-layer structure. According to one of the two methods, the oxide film 4 is formed on the semiconductor layer 2, and the Ge layer 6A₂ and the Si layer 6A₃ are formed sequentially on a SOI (Si-On-Insulator) substrate having the Si layer 6A₁ formed thereon, through epitaxial growth using UHVCVD (Ultra High Vacuum Chemical Vapor Deposition), LPCVD (Low Pressure Chemical Vapor Deposition), MBE (Molecular Beam Epitaxy), or the like, as shown in FIG. 12. According to the other method, STI (Shallow Trench Isolation) 30 is formed on a SOI substrate, and the Ge layer 6A₂ and the Si layer 6A₃ are formed sequentially on the Si layer 6A₁ through epitaxial growth using UHVCVD, LPCVD, MBE, or the like, as shown in FIG. 13.

By forming the semiconductor layer 6A having the above described structure, the reliability of the interface between the gate insulating film 8 and the Si layer 6A₃ of the semiconductor layer 6A, and the reliability of the interface between the oxide film 4 and the Si layer 6A₁ of the semiconductor layer 6A can be secured, and the efficiency of impact ionization caused by the channel layer formed of the Ge layer 6A₂ can be made higher.

The structure of the fourth embodiment may be applied to the transistor of the first embodiment.

In the fourth embodiment, the transistor also has a symmetrical structure in which the source/drain regions have the same conductivity type, as in the first or second embodiment. Therefore, a conventional circuit design technique can be used as it is in the device layout. Accordingly, the area increase and the cost increase that accompany a change of design can be restrained.

### Fifth Embodiment

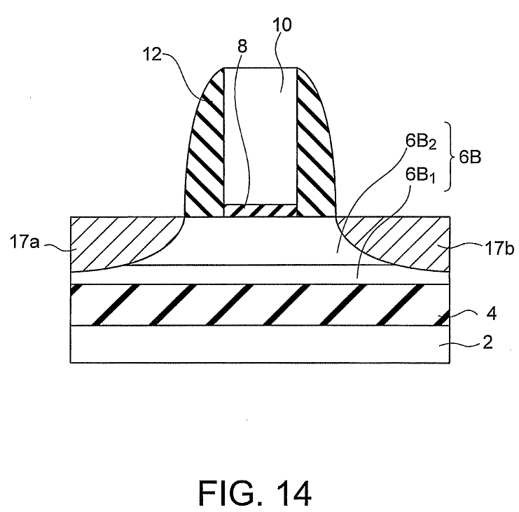

FIG. 14 shows a transistor according to a fifth embodiment. The transistor of the fifth embodiment is the same as the transistor of the second embodiment illustrated in FIG. 5, except that the semiconductor layer 6 is replaced with a semiconductor layer 6B made of SiGe, and the semiconductor layer 6B has a double-layer structure that includes a Si layer 6B₁ formed on the side of the oxide film 4 and a Si₁₋ₓGeₓ (0<x≦1) layer formed on the side of the gate insulating film 8. In the following description, the Si₁₋ₓGeₓ (0<x≦1) layer is a Ge layer 6B₂.

The semiconductor layer 6B having such a Ge profile can be formed by epitaxially growing and/or oxidizing and Ge condensing a SiGe layer. Also, as described in the fourth embodiment, prior to or after the formation of STI (Shallow Trench Isolation) 30 with the use of a SOI substrate, the Ge layer 6B₂ may be formed on the Si layer 6B₁ through epitaxial growth using UHVCVD, LPCVD, MBE, or the like.

By forming the semiconductor layer 6B having the above described structure, the reliability of the interface between the oxide film 4 and the Si layer 6B₁ can be secured, and the efficiency of impact ionization caused by the channel layer formed of the Ge layer 6B₂ can be made higher.

The structure of the fifth embodiment may be applied to the transistor of the first embodiment.

In the fifth embodiment, the transistor also has a symmetrical structure in which the source/drain regions have the same conductivity type, as in the first or second embodiment. Therefore, a conventional circuit design technique can be used as it is in the device layout. Accordingly, the area increase and the cost increase that accompany a change of design can be restrained.

### Sixth Embodiment

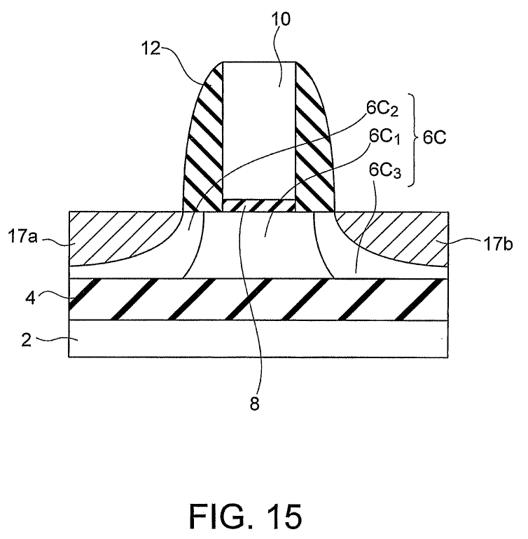

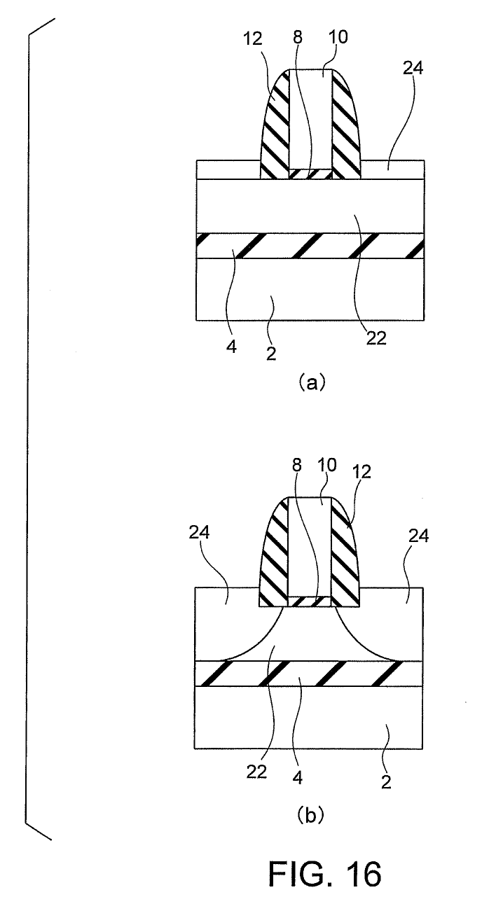

FIG. 15 shows a transistor according to a sixth embodiment. The transistor of the sixth embodiment is the same as the transistor of the second embodiment illustrated in FIG. 5, except that the semiconductor layer 6 is replaced with a semiconductor layer 6C made of SiGe, and the semiconductor layer 6C has a structure in which the channel region located immediately below the gate electrode 10 is a Si layer 6C₁, and Si₁₋ₓGeₓ (0<x≦1) layers are formed on both sides of the Si layer 6C₁. In the following description, the Si₁₋ₓGeₓ (0<x≦1) layers formed on both sides of the Si layer 6C₁ are Ge layers 6C₂ and 6C₃. The Ge layers 6C₂ and 6C₃ extend to regions located immediately below the sidewalls 12. The transistor having such a structure is manufactured in the manner illustrated in FIGS. 16(a) and 16(b). A SOI (Silicon On Insulator) substrate including the semiconductor layer 2 made of Si, the oxide film 4 formed on the semiconductor layer 2, and a Si layer 22 is prepared, and the gate insulating film 8 and the gate electrode 10 are formed on the Si layer 22. Subsequently, the sidewalls 12 made of a high dielectric material are formed at the side portions of the gate electrode 10. After that, SiGe layers or Ge layers 24 are formed through selective epitaxial growth performed on the regions to serve as the source region and the drain region, i.e. the regions of the Si layer 22 located on both sides of the gate electrode 10 (FIG. 16(a)). Ge is then diffused in the regions to service the source region and the drain region by oxidation and condensation, thereby forming the Ge layers 24 (FIG. 16(b)).

In the sixth embodiment described above, the Si layer 6C₁ is located on the side of the gate insulating film 8. Accordingly, degradation of the characteristics of the interface between the gate insulating film 8 and the Si layer 6C₁ due to diffusion of Ge can be restrained. Also, since the drain end is formed of the Ge layer 6C₃, the efficiency of impact ionization can be made higher.

The structure of the sixth embodiment may be applied to the transistor of the first embodiment.

In the sixth embodiment, the transistor also has a symmetrical structure in which the source/drain regions have the same conductivity type, as in the first or second embodiment. Therefore, a conventional circuit design technique can be used as it is in the device layout. Accordingly, the area increase and the cost increase that accompany a change of design can be restrained.

The transistors of the first through sixth embodiments can be used in a memory known as a FBC (Floating Body Cell). In that case, a memory embedded logic LSI that has ultrahigh integration and consumes a very low amount of power can be realized without a change in device structure.

Also, with the use of the transistors of the first through sixth embodiments, the supply voltage of the logic circuit can be greatly reduced without a change in conventional circuit design.

### Seventh Embodiment

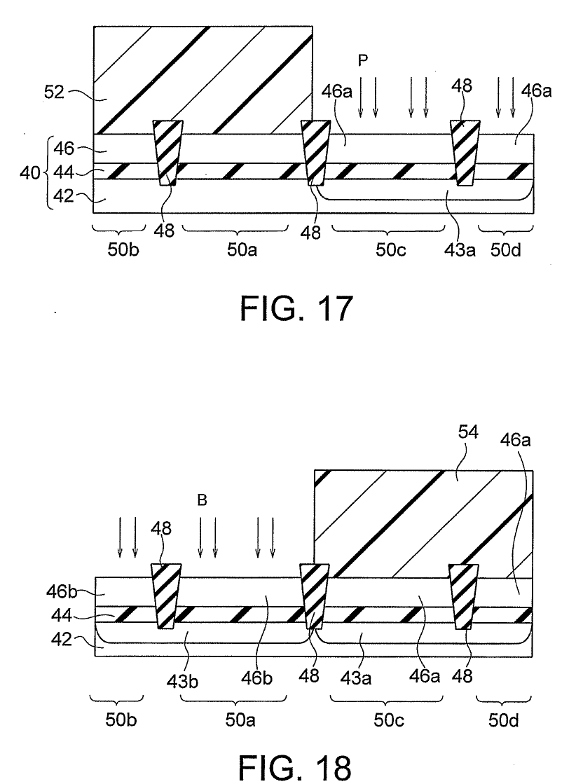

Referring now to FIGS. 17 through 24, a method of manufacturing a CMOS transistor according to a seventh embodiment is described.

First, a strained GOI (Ge-On-Insulator) substrate 40 including a semiconductor layer 42, an oxide film 44, and a Ge layer 46 is prepared. Next, STI 48 to serve as the device isolation regions is formed in the GOI substrate 40, and the GOI substrate 40 is divided into a region 50a for forming an n-channel transistor (also referred to as the n-FET), a region 50b for forming a backgate contact for the n-FET, a region 50c for forming a p-channel transistor (also referred to as the p-FET), and a region 50d for forming a backgate contact for the p-FET. A mask 52 that has openings on the regions 50c and 50d, covers the region 50a and the region 50b, and is made of a photoresist, for example, is formed. With the use of the mask 52, an n-type dopant, such as one of P, As, and Sb, is introduced into the regions 50c and 50d, thereby forming an n-well region 43a in the semiconductor layer 42 (FIG. 17). At this point, the portions of the semiconductor layer 46 located in the regions 50c and 50d turn into n-type semiconductor layers 46a.

After the mask 52 is removed, a mask 54 that has openings on the regions 50a and 50b, covers the region 50c and the region 50d, and is made of a photoresist, for example, is formed. With the use of the mask 54, a p-type dopant, such as one of B, Ga, and In, is introduced into the regions 50a and 50b, thereby forming a p-well region 43b in the semiconductor layer 42 (FIG. 18). At this point, the portions of the semiconductor layer 46 located in the regions 50a and 50b turn into p-type semiconductor layers 46b.

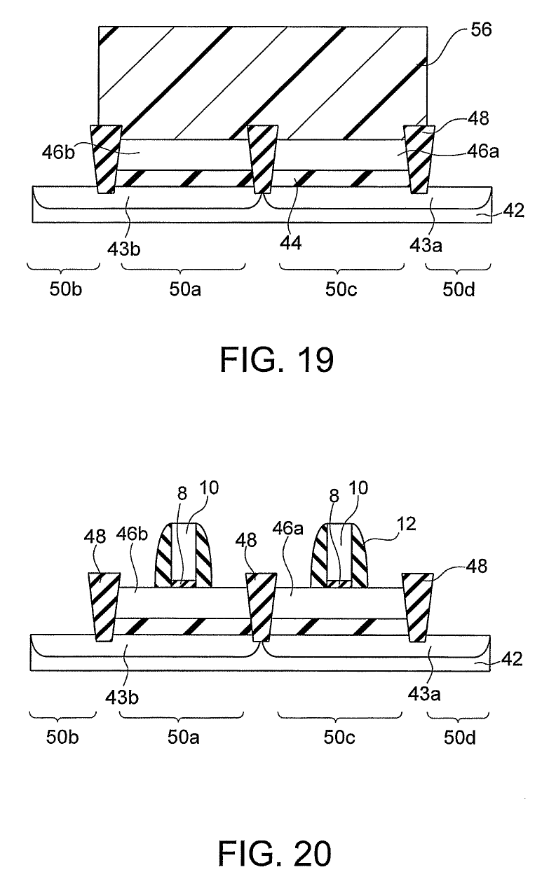

After the mask 54 is removed, a mask 56 that has openings on the regions 50b and 50d, covers the region 50a and the region 50c, and is made of a photoresist, for example, is formed. With the use of the mask 56, etching is performed on the portions of the semiconductor layers 46a and 46b and the oxide film 44 located in the regions 50b and 50d, thereby removing those portions. As a result, the portions of the p-well region 43b and the n-well region 43a located in the region 50b and the region 50d are exposed (FIG. 19).

After the mask 56 is removed, gate structures each including the gate insulating film 8, the gate electrode 10, and the gate sidewalls 12 are formed on the semiconductor layer 46b in the region 50a and the semiconductor layer 46a in the region 50c (FIG. 20). The gate insulating film 8 is made of SiO₂, SiON, GeO₂, GeON, HfO₂, Al₂O₃, HfAlₓO_{y}, HfLaO, or LaₓO_{y}, for example. The gate electrode 10 is made of polysilicon or metal, or is formed of a stack structure containing polysilicon and metal. The gate sidewalls 12 are made of a high dielectric material.

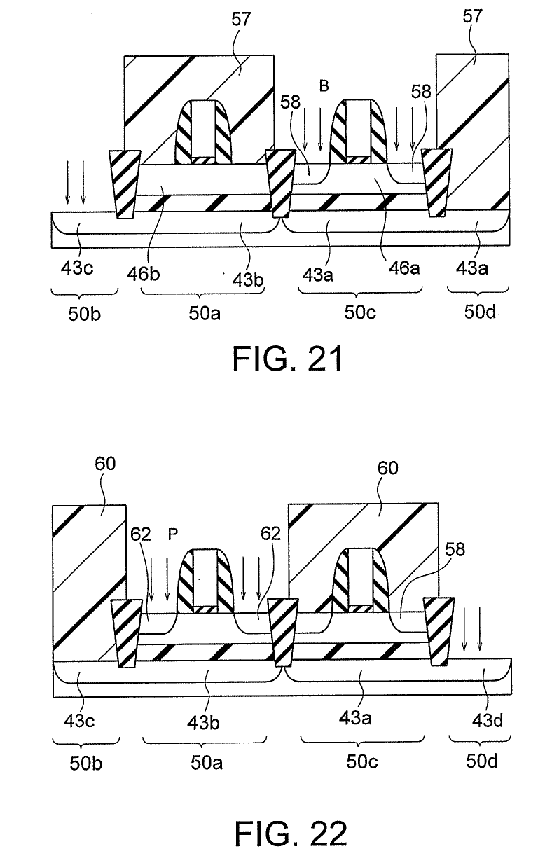

A mask 57 that has openings on the regions 50b and 50c, covers the regions 50a and 50d, and is made of a photoresist, for example, is then formed. With the use of the mask 57, a p-type dopant is introduced into the p-well region 43b in the region 50b, and a p-type dopant is introduced into the n-type semiconductor layer 46a in the region 50c. The p-type dopants introduced here respectively have a concentration of approximately 1×10¹⁵ cm⁻², for example. As a result, the p-well region 43b in the region 50b turns into a high-concentration p-well region 43c, and p-type source and drain regions 58 are formed in the n-type semiconductor layer 46a in the region 50c (FIG. 21).

After the mask 57 is removed, a mask 60 that has openings on the regions 50a and 50d, covers the regions 50b and 50c, and is made of a photoresist, for example, is formed. With the use of the mask 60, an n-type dopant is introduced into the n-well region 43a in the region 50d, and an n-type dopant is introduced into the p-type semiconductor layer 46b in the region 50a. The n-type dopants introduced here respectively have a concentration of approximately 1×10¹⁵ cm⁻², for example. At this point, together with the n-type dopants, at least one element of S and Se for schottky barrier modulation is introduced at approximately 1×10¹⁵ cm⁻². As a result, the n-well region 43a in the region 50d turns into a high-concentration n-well region 43d, and n-type source and drain regions 62 are formed in the p-type semiconductor layer 46b in the region 50a (FIG. 22).

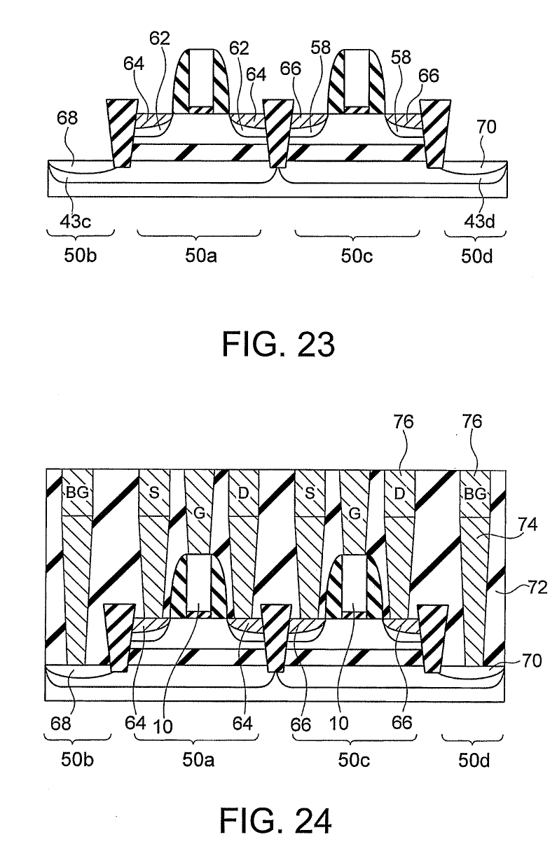

After the mask 60 is removed, a 10-nm Ni film is deposited on the entire surface by sputtering, and a 1-minute heat treatment at 250° C. is performed through RTA (Rapid Thermal Annealing). After the unreacted Ni is selectively removed by a chemical solution treatment, a 1-minute heat treatment at 350° C. is again performed through RTA. As a result, Germanides are formed in the n-type source and drain regions 62 in the region 50a, thereby forming metallic source and drain electrodes 64. Also, Germanides are formed in the p-type source and drain regions 58 in the region 50c, thereby forming metallic source and drain electrodes 66. Further, Germanides are formed in the p-well region 43c in the region 50b and the n-well region 43d in the region 50d, thereby forming backgate electrodes 68 and 70, respectively (FIG. 23). At this point, the dopants for schottky barrier modulation introduced for forming the n-type source and drain regions 62 are segregated in the interfaces between the source and drain electrodes 64 and the source and drain regions 62, and the schottky barriers are modulated.

As shown in FIG. 24, an interlayer insulating film 72 is then deposited, and openings connected to the gate electrodes 10, the source and drain electrodes 64 and 66, and the backgate electrodes 68 and 70 of the n-FET and the p-FET are formed in the interlayer insulating film 72. Those openings are filled with metal, thereby forming contacts 74 and interconnects 76. In this manner, the CMOS transistor is completed.

Like the transistor of the first embodiment, the CMOS transistor of this embodiment manufactured in the above-described manner can achieve steep S-value characteristics, and has a symmetrical structure in which the source/drain regions have the same conductivity type. Therefore, a conventional circuit design technique can be used as it is in the device layout. Accordingly, the area increase and the cost increase that accompany a change of design can be restrained.

While certain embodiments have been described, these embodiments have been presented by way of example only, and are not intended to limit the scope of the inventions. Indeed, the novel methods and systems described herein can be embodied in a variety of other forms; furthermore, various omissions, substitutions and changes in the form of the methods and systems described herein can be made without departing from the spirit of the inventions. The accompanying claims and their equivalents are intended to cover such forms or modifications as would fall within the scope and spirit of the inventions.

What is claimed is:

1. A field effect transistor comprising:
a semiconductor layer;
a source region and a drain region formed at a distance from each other in the semiconductor layer;
a gate insulating film formed on a portion of the semiconductor layer, the portion being located between the source region and the drain region;
a gate electrode formed on the gate insulating film; and
a gate sidewall formed on at least one of side faces of the gate electrode, the side faces being located on a side of the source region and on a side of the drain region, the gate sidewall being made of a high dielectric material,
wherein the source region and the drain region are separately-placed from the corresponding side faces of the gate electrode.

2. The transistor according to claim 1, wherein a source electrode and a drain electrode are formed in the source region and the drain region, respectively, the source electrode and the drain electrode containing an intermetallic compound of the semiconductor layer and metal.

3. The transistor according to claim 2, wherein
the distance between the source electrode and the gate electrode is longer than the distance between the source region and the gate electrode, and
the distance between the drain electrode and the gate electrode is longer than the distance between the drain region and the gate electrode.

4. The transistor according to claim 1, wherein each of the source region and the drain region is made of an intermetallic compound of the semiconductor layer and metal.

5. The transistor according to claim 4, wherein
the semiconductor layer is a p-type semiconductor, and
at least one element of S and Se is segregated in an interface between the source region and the semiconductor layer and in an interface between the drain region and the semiconductor layer.

6. The transistor according to claim 1, wherein an extension region containing a dopant is formed between the source region and a region of the semiconductor layer, the region being located immediately below the gate electrode.

7. The transistor according to claim 6, wherein the gate side wall is formed on the side face of the gate electrode on the side of the drain region, another gate side wall is formed on a side face of the gate electrode on the side of the source region and is made of a low dielectric material.

8. The transistor according to claim 6, wherein the gate side walls are formed on the side faces of the gate electrode, and are made of a high dielectric material.

9. The transistor according to claim 1, wherein the semiconductor layer is a strained Si₁₋ₓGeₓ (0≦x≦1) layer.

10. The transistor according to claim 9, wherein the semiconductor layer is formed on an insulating film, and includes a first Si layer formed on a side of the insulating film, a second Si layer formed on a side of the gate insulating film, and a Si₁₋ₓGeₓ (0<x≦1) layer formed between the first Si layer and the second Si layer.

11. The transistor according to claim 9, wherein the semiconductor layer is formed on an insulating film, and includes a first Si layer formed on a side of the insulating film and a Si₁₋ₓGeₓ (0<x≦1) layer formed on a side of the gate insulating film.

12. The transistor according to claim 9, wherein the semiconductor layer includes a first region located immediately below the gate electrode, and second and third regions formed on both sides of the first region, the first region being made of Si, the second and third regions being made of Si₁₋ₓGeₓ (0<x≦1).
